(19) United States
(12) Patent Application Publication
(10) Pub. No.: US 2026/0342305 A1
(43) Pub. Date: Oct. 29, 2026

(54) ELASTIC WAVE RESONATOR, ELASTIC WAVE FILTER, AND COMMUNICATION DEVICE

(71) Applicant: KYOCERA Corporation, Kyoto-shi, Kyoto (JP)

(72) Inventor: Tomohiro ANDO, Kyotanabe-shi (JP)

(73) Assignee: KYOCERA Corporation, Kyoto-shi, Kyoto (JP)

(21) Appl. No.: 19/099,690

(22) PCT Filed: Jul. 25, 2023
(86) PCT No.: PCT/JP2023/027168

§ 371 Date: Jan. 29, 2025

(30) Foreign Application Priority Data
Jul. 29, 2022 (JP) 2022-121813

(51) Int. Cl. H03H 9/02; H03H 9/64

(52) U.S. Cl. CPC H03H 9/02228; H03H 9/02007; H03H 9/64

(57) ABSTRACT

An acoustic wave resonator includes a piezoelectric layer and an IDT electrode. The piezoelectric layer has a piezoelectric property. The IDT electrode is positioned on a first surface of the piezoelectric layer and includes multiple electrode fingers arrayed in a first direction. An entirety of each of the multiple electrode fingers is positioned in an electrode finger arrangement region. A distance from one side of one electrode finger to a corresponding one side of an electrode finger adjacent to the one electrode finger in the first direction is defined as a pitch of the one electrode finger. The electrode finger arrangement region includes a first region in which the pitches of all the electrode fingers are different from each other. The acoustic wave resonator is configured so that a plate wave or a bulk wave is used as an acoustic wave that propagates through the electrode finger arrangement region.

### TECHNICAL FIELD

The present invention relates to an acoustic wave resonator, which is an electronic component that utilizes acoustic waves, to an acoustic wave filter including the acoustic wave resonator, and to a communication device.

### BACKGROUND OF INVENTION

A known acoustic wave resonator generates acoustic waves that propagate through a piezoelectric body by applying a voltage to an IDT (interdigital transducer) electrode, which consists of multiple electrode fingers provided on the surface of a piezoelectric substrate. The IDT electrode is configured to include a gradation region in which the electrode finger pitch gradually decreases at both ends of the IDT electrode. This configuration allows a surface acoustic wave resonator to be obtained in which ripples are small.

### CITATION LIST

### Patent Literature

Patent Literature 1: Japanese Unexamined Patent Application Publication No. 2012-138964

### SUMMARY

In an embodiment of the present invention, an acoustic wave resonator includes a piezoelectric layer and an IDT electrode. The piezoelectric layer has a piezoelectric property. The IDT electrode is positioned on a first surface of the piezoelectric layer and includes multiple electrode fingers arrayed in a first direction. An entirety of each of the multiple electrode fingers is positioned in an electrode finger arrangement region. A distance from one side of one electrode finger to a corresponding one side of the electrode finger adjacent to the one electrode finger in the first direction is defined as a pitch of the one electrode finger. The electrode finger arrangement region includes a first region in which the pitches of all the electrode fingers are different from each other. The acoustic wave resonator is configured so that a plate wave or a bulk wave is used as an acoustic wave that propagates through the electrode finger arrangement region.

In an embodiment of the present invention, an acoustic wave resonator includes a piezoelectric layer and an IDT electrode. The piezoelectric layer has a piezoelectric property. The IDT electrode is positioned on a first surface of the piezoelectric layer and includes multiple electrode fingers arrayed in a first direction. An entirety of each of the multiple electrode fingers is positioned in an electrode finger arrangement region. A distance from one side of one electrode finger to a corresponding one side of the electrode finger adjacent to the one electrode finger in the first direction is defined as a pitch of the one electrode finger. The pitches of the electrode fingers increase in a direction toward the one side in a central region obtained when the electrode finger arrangement region is divided into three equal parts in the first direction.

In an embodiment of the present invention, an acoustic wave filter is a ladder acoustic wave filter. The acoustic wave filter includes multiple series arm resonators connected in series with each other and a parallel arm resonator connected in parallel with the series arm resonators. The multiple series resonators include any one of the above-described acoustic wave resonators and a second acoustic wave resonator. An anti-resonance frequency of the second acoustic wave resonator is positioned closer to a passband of the acoustic wave filter than an anti-resonance frequency of the acoustic wave resonator is. P1max is defined as a largest pitch and P1min is defined as a smallest pitch among the pitches of multiple electrode fingers of the IDT electrode of the acoustic wave resonator. P2max is defined as a largest pitch and P2min is defined as a smallest pitch among pitches of multiple electrode fingers of an IDT electrode of the second acoustic wave resonator. (P2max−P2min) is smaller than (P1max−P1min).

In an embodiment of the present invention, an acoustic wave filter is a ladder acoustic wave filter. The acoustic wave filter includes a series arm resonator connected in series and multiple parallel arm resonators connected in parallel with the series arm resonator. The multiple parallel arm resonators include any one of the above-described acoustic wave resonators and a second acoustic wave resonator. A resonance frequency of the second acoustic wave resonator is positioned closer to a passband of the acoustic wave filter than a resonance frequency of the acoustic wave resonator is. P1max is defined as a largest pitch and P1min is defined as a smallest pitch among the pitches of multiple electrode fingers of the IDT electrode of the acoustic wave resonator. P2max is defined as a largest pitch and P2min is defined as a smallest pitch among pitches of multiple electrode fingers of an IDT electrode of the second acoustic wave resonator. (P2max−P2min) is smaller than (P1max−P1min).

In an embodiment of the present invention, an acoustic wave filter includes any one of the above-described acoustic wave resonators. A maximum phase of spurious originating from the acoustic wave resonator and present in a passband of the acoustic wave filter is less than or equal to −70 °.

In an embodiment of the present invention, a communication device includes an antenna, an acoustic wave filter connected to the antenna, and an IC connected to the acoustic wave filter. The acoustic wave filter includes the above acoustic wave resonator.

### BRIEF DESCRIPTION OF THE DRAWINGS

FIG. 1 is a schematic sectional view of an acoustic wave resonator according to an embodiment of the present invention.

FIG. 2 is a plan view of the acoustic wave resonator according to an embodiment of the present invention.

FIG. 3 is a plan view of the acoustic wave resonator according to an embodiment of the present invention.

FIG. 4A is a diagram illustrating the resonance characteristics of the acoustic wave resonator according to an embodiment of the present invention.

FIG. 4B is another diagram illustrating the resonance characteristics of the acoustic wave resonator according to an embodiment of the present invention.

FIG. 4C is yet another diagram illustrating the resonance characteristics of the acoustic wave resonator according to an embodiment of the present invention.

FIG. 5 is a diagram illustrating the pitch difference required to express a frequency difference of 50 MHz in a resonator with an anti-resonance frequency of 4600 MHz to 4950 MHz.

FIG. 6A is a schematic sectional view of an acoustic wave resonator according to another embodiment of the present invention.

FIG. 6B is a schematic sectional view of an acoustic wave resonator according to yet another embodiment of the present invention.

FIG. 7 is a diagram schematically illustrating an acoustic wave filter as a usage example of an acoustic wave resonator according to an embodiment of the present invention.

FIG. 8 is a block diagram illustrating the configuration the main components of a communication device as a usage example of an acoustic wave resonator according to an embodiment of the present invention.

### DESCRIPTION OF EMBODIMENTS

Hereafter, embodiments according to the present invention will be described while referring to the drawings. The drawings used in the following description are schematic drawings, and the proportions of the dimensions and so forth in the drawings do not necessarily correspond to the actual proportions of the dimensions and so forth.

A Cartesian coordinate system consisting of an X-axis, a Y-axis, and a Z-axis is added to these figures for convenience. Any direction may be considered as up or down with respect to an acoustic wave resonator 1 according to the present invention. However, for convenience, the words “top surface” and “bottom surface” may be used with the Z-axis direction being regarded as an up-down direction. The X-axis is defined as parallel to the propagation direction of SAW (surface acoustic waves) that propagate along the top surface of a piezoelectric layer 2, which will be described later, the Y-axis is defined as parallel to the top surface of the piezoelectric layer 2 and perpendicular to the X-axis, and the Z-axis is defined as perpendicular to the top surface of the piezoelectric layer 2.

Furthermore, the embodiments described in the present specification are for illustrative purposes only, and parts may be substituted for one another between different embodiments. In additions, parts of different embodiments may be combined with each other.

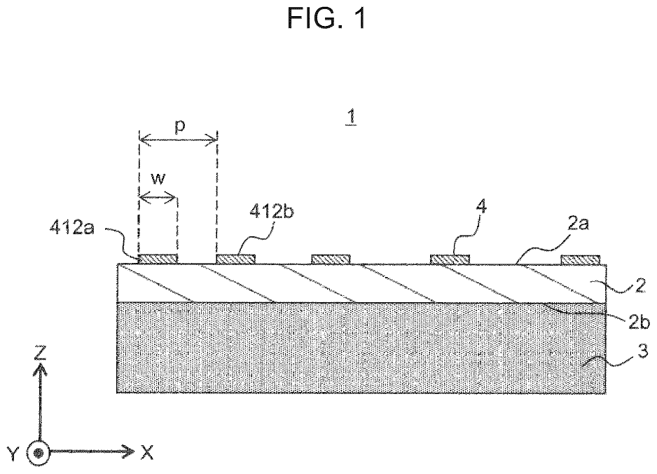

FIG. 1 is a schematic sectional view of the acoustic wave resonator 1 according to an embodiment of the present invention.

In an embodiment of the present invention, the acoustic wave resonator 1 includes the piezoelectric layer 2, a support substrate 3, and an IDT electrode 4, as illustrated in FIG. 1. The support substrate 3 and the piezoelectric layer 2 are stacked in this order.

The support substrate 3 functions to support the piezoelectric layer 2 stacked thereon. The material of the support substrate 3 is not particularly limited so long as the material has a certain strength. For example, if the support substrate 3 is composed of a material having a lower linear expansion coefficient than the piezoelectric layer 2, deformation of the piezoelectric layer 2 due to changes in temperature can be reduced, and as a result, changes in resonance characteristics due to changes in temperature can be reduced. In addition, the material of the support substrate 3 may be a material having a higher transverse wave acoustic velocity for acoustic waves propagating therethrough compared to the transverse wave acoustic velocity for acoustic waves propagating through the piezoelectric layer 2. When a material is selected for the support substrate 3 that has a higher transverse wave acoustic velocity for acoustic waves propagating therethrough compared to the transverse wave acoustic velocity of acoustic waves propagating through the piezoelectric layer 2, the acoustic waves can be confined to the piezoelectric layer 2, and the acoustic wave resonator 1 having excellent frequency characteristics can be provided.

Examples of such a material include sapphire (Al₂O₃) and silicon (Si), for example. In this embodiment, a case where Si is used for the support substrate 3 will be described as an example.

The thickness of the support substrate 3 is not particularly limited, but for example, may be greater than the thickness of the piezoelectric layer 2, which is described later.

The piezoelectric layer 2 has a top surface 2a and a bottom surface 2b that are perpendicular to the Z-axis, the Z-axis corresponding to an up-down direction. The previously mentioned support substrate 3 is positioned on the bottom surface 2b side. The bottom surface 2b and the support substrate 3 may be in direct contact with each other, or may be in indirect contact with each other with an intermediate layer, a multilayer film layer 5, and so forth, interposed therebetween as described below. In addition, the bottom surface 2b and the support substrate 3 may be in indirect contact with each other with an adhesive layer, etc., which is not illustrated, interposed therebetween. The IDT electrode 4, which is described below, is positioned on the top surface 2a side.

For the piezoelectric layer 2, for example, a single-crystal substrate having piezoelectric properties composed of lithium tantalate (LiTaO₃; hereafter referred to as LT) crystal or a single-crystal substrate having piezoelectric properties composed of lithium niobate (LiNbO₃; hereafter referred to as LN) crystal can be used. In this embodiment, specifically, the piezoelectric layer 2 is composed of 120 ° Y-cut X-propagation LN.

When a radio-frequency signal is applied to the IDT electrode 4, which is described below, acoustic waves are excited that propagate through the piezoelectric layer 2 in the propagation direction of the acoustic waves. The propagation direction may be any direction, and for example, may extend along the top surface and bottom surface of the piezoelectric layer 2 and/or the thickness direction of the piezoelectric layer 2. In the acoustic wave resonator 1 of this embodiment, the excited acoustic waves include plate waves or bulk waves. In the acoustic wave resonator 1, plate waves or bulk waves may be used as a main mode.

There are no particular restrictions on the types of acoustic waves used. For example, the plate waves may be Lamb waves. For example, the bulk waves may be SH waves or thickness shear waves. In addition, the propagation mode of the plate waves used is not particularly limited. Specifically, in this embodiment, the plate waves may be the A1 mode of Lamb waves.

Incidentally, Lamb waves mainly include a component in the direction in which electrode fingers 412 are arrayed (propagation direction) (P component) and/or a component in the thickness direction of the piezoelectric layer 2 (SV component). The A1 mode refers to a first-order asymmetric mode (A mode) (i.e. mode having one node in the thickness direction). The SH waves mainly include a component (SH component) in a direction perpendicular to the direction in which the electrode fingers 412 are arrayed (propagation direction) and horizontal along the surface of the piezoelectric layer 2. The thickness shear waves cause different parts of the piezoelectric layer 2 in the thickness direction (for example, the top surface and the bottom surface) to slide in directions along the top surface and bottom surface of the piezoelectric layer 2 and propagate in the thickness direction of the piezoelectric layer 2. The order of the thickness shear waves may be any order, and, for example, is first order (i.e., there is one node in the thickness direction).

The thickness of the piezoelectric layer 2 may be set as appropriate so long as the plate waves can be used at that thickness. For example, in this embodiment, the thickness of the piezoelectric layer 2 is 2λ or less when the thickness is expressed using λ as described below.

The IDT electrode 4 is positioned on the top surface 2a of the piezoelectric layer 2. The IDT electrode 4 is composed of an electrically conductive material. A variety of conductive materials, such as Al, Cu, Pt, Mo, Au, or alloys of these materials can be used as the material of the IDT electrode 4, and a configuration may be adopted in which multiple layers of these materials are stacked together. In addition, when the IDT electrode 4 is composed of a multilayer body consisting of multiple layers, a base layer, which is not illustrated, may be interposed at an interface between the layers. In this embodiment, specifically, the IDT electrode 4 is composed of A1.

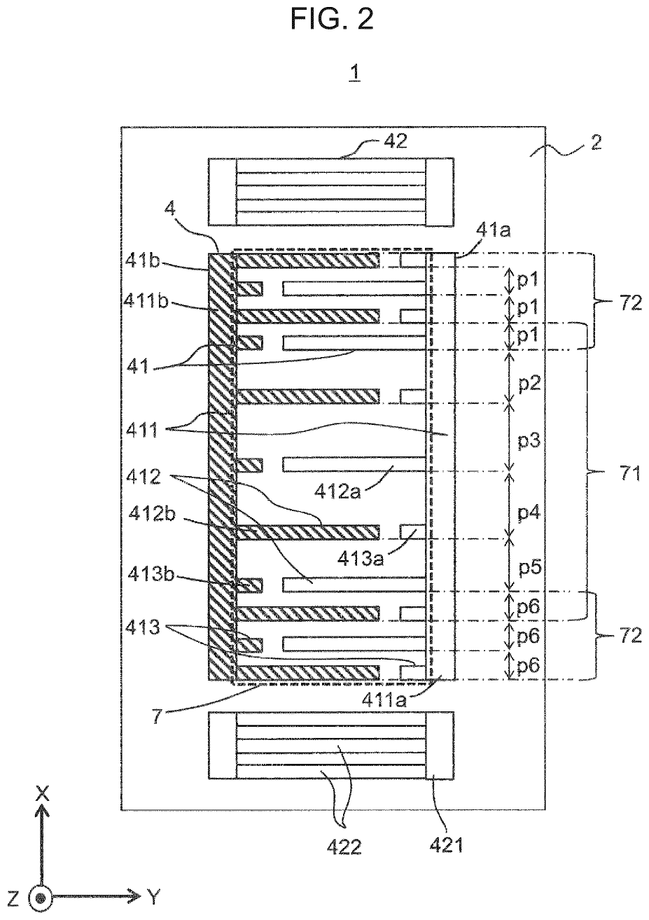

FIG. 2 schematically illustrates the shape of the IDT electrode 4 when viewed in plan view in the Z-axis direction. As illustrated in FIG. 2, the IDT electrode 4 includes a pair of comb-shaped electrodes 41.

The comb-shaped electrodes 41 (41a and 41b) include, for example, busbars 411 (411a and 411b) and multiple electrode fingers 412 (412a and 412b) extending from the busbars 411. The electrode fingers 412a connected to one busbar 411a and the electrode fingers 412b connected to the other busbar 411b are disposed so as to mesh with each other. In addition, the comb-shaped electrodes 41 may include multiple dummy electrode fingers 413 (413a and 413b) that protrude from one busbar 411 and face the electrode fingers 412 extending from the other busbar 411 between the multiple electrode fingers 412.

The length of the multiple electrode fingers 412 in the Y-axis direction may be set as appropriate in accordance with the required electrical characteristics, etc. For example, the multiple electrode fingers 412 may have the same length as each other in the Y-axis direction. In addition, the IDT electrode 4 may be subjected to so-called apodization, in which the length (or, from another perspective, the crossing width) of the multiple electrode fingers 412 in the Y-axis direction changes depending on the position in the propagation direction.

The acoustic wave resonator 1 may further include a pair of reflectors 42 on the top surface of the piezoelectric layer 2. The pair of reflectors 42 are positioned on both sides of the IDT electrode 4 in the propagation direction of acoustic waves. In other words, each reflector 42 includes a pair of reflector busbars 421, which face each other, and multiple strip electrodes 422 extending between the pair of reflector busbars 421.

The thickness of the multiple electrode fingers 412 in the Z-axis direction may be set as appropriate in accordance with the required electrical characteristics, etc. For example, the thickness of the multiple electrode fingers 412 in the Z-axis direction may be constant.

As illustrated in FIG. 1, the width of one electrode finger 412a in the X-axis direction is defined as a width (w) of the electrode finger 412a. The distance from one side of the one electrode finger 412a to one side of the electrode finger 412b that is adjacent to electrode finger 412a is defined as a pitch (p) of the electrode finger 412a. A duty d of the electrode finger 412a is the ratio of the width to the pitch of electrode finger 412a. In other words, the duty d of electrode finger 412a can be expressed in terms of width/pitch (w/p).

The multiple electrode fingers 412 are disposed with a spacing therebetween based on a prescribed pitch. In addition, the resonance frequency of acoustic waves excited by the acoustic wave resonator 1, among the acoustic waves propagating in the piezoelectric layer 2, depends on the pitch of the electrode fingers 412.

In the acoustic wave resonator 1 of this embodiment, as illustrated in FIG. 2, the entirety of each of the multiple electrode fingers 412 of the IDT electrode 4 is positioned within an electrode finger arrangement region 7 in plan view. In other words, the electrode finger arrangement region 7 is the region in which the entirety of each of the multiple electrode fingers 412 is positioned in plan view. In FIG. 2, for convenience, the electrode finger arrangement region 7 is indicated using a dotted line. In this embodiment, the electrode finger arrangement region 7 includes at least one first region 71.

In this embodiment, the pitches of all the electrode fingers 412 positioned in the first region 71 are different from each other. Specifically, in FIG. 2, pitches P1 to P6 of all the electrode fingers in the first region 71 are different from each other. In this way, by making the pitches of the electrode fingers 412 different from each other, the resonance of various unwanted waves, including second- and third-order waves, is reduced, and the generation of spurious can be reduced.

In this specification, λ is defined as twice the largest pitch among the pitches of the multiple electrode fingers positioned in the first region. Generally, λ is often used as the symbol for wavelength. However, in acoustic wave resonator 1, the wavelength of the plate waves may be the same size as λ but does not need to be the same size as λ. For example, the wavelength of A1 mode Lamb waves tends to be relatively close to λ. On the other hand, the wavelength of the thickness shear waves has a dependence on λ, but the dependence on the thickness of the piezoelectric layer 2 is relatively large, and is not necessarily close to λ.

In this embodiment, the electrode finger arrangement region 7 may also include second regions 72. The pitches of all the electrode fingers 412 in the second regions 72 are identical. Note that, in this specification, “constant pitch” does not necessarily mean that the pitch is strictly constant, and some variation within a range that can be termed manufacturing error is allowed. The range that can be termed manufacturing error is, for example, a range of 1.5% or less of the average value of the pitches of the electrode fingers 412 positioned in that region. However, for example, even if the difference between adjacent pitches is 1.5% or less as described above, if the pitches are clearly not intended to be constant when making an overall judgment based on the pitch change tendencies etc. in a region that includes the above-mentioned adjacent pitches, the pitches of the above-mentioned adjacent pitches do not necessarily need to be considered to be constant.

The electrode finger 412 positioned at the boundaries between the first region 71 and each second region 72 may be interpreted as being included in both the first region and the second region. Similarly, the electrode fingers 412 positioned at the boundaries between the central region and the regions on either side described above may also be interpreted as being included in the central region.

In this embodiment, the acoustic wave resonator 1 uses plate waves as a main mode. The resonance characteristics of plate waves greatly depend on the thickness of the piezoelectric layer 2. On the other hand, the resonance of plate waves is not easily affected by differences in pitch between the electrode fingers 412. Therefore, in this embodiment, the acoustic wave resonator 1 uses plate waves, and the pitches of all the electrode fingers 412 positioned in the first region 71 are different from each other, and therefore the resonance of spurious modes caused by unwanted waves can be effectively reduced while maintaining the resonance of the main mode due to plate waves to a relatively good degree. Using plate waves as the main mode means that the main mode of the acoustic waves excited by the IDT electrode 4 is made up of plate waves.

As illustrated in FIG. 2, the first region 71 may occupy at least half the area of the electrode finger arrangement region 7. With this configuration, the region in which pitches of the electrode fingers 412 are different from each other is dominant, and the generation of large phase spurious can be more effectively reduced.

In addition, as illustrated in FIG. 2, the area near the center of the electrode finger arrangement region 7 in the direction in which the electrode fingers 412 are arrayed may belong to the first region 71. The area near the center is, for example, the region in the center when the electrode finger arrangement region 7 is divided into three equal parts in the direction in which the electrode fingers 412 are arrayed.

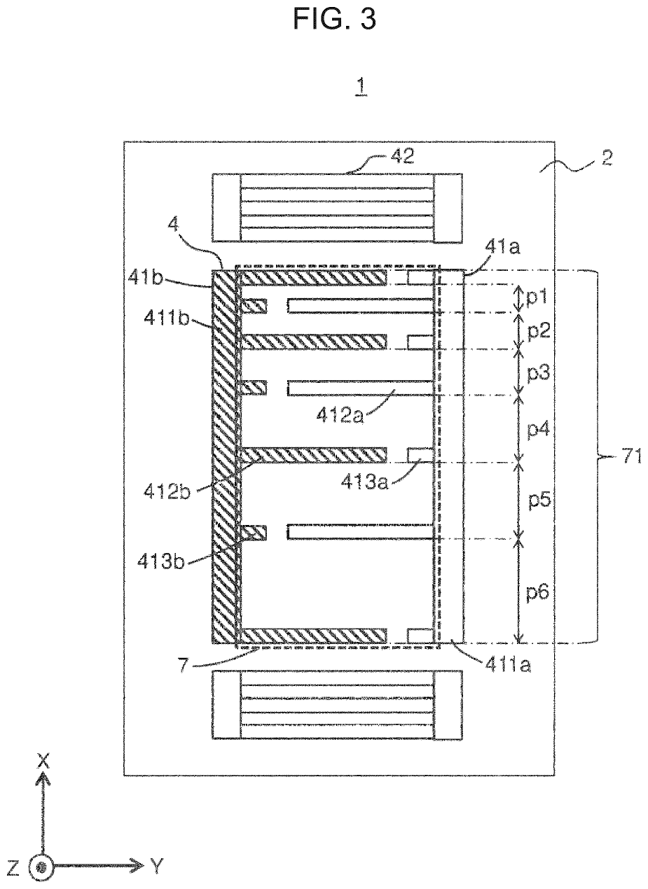

In addition, as illustrated in FIG. 3, the entire electrode finger arrangement region 7 may belong to the first region 71. By adopting this configuration, the proportion occupied by the region in which generation of spurious is reduced becomes even larger, and generation of spurious can be reduced more effectively.

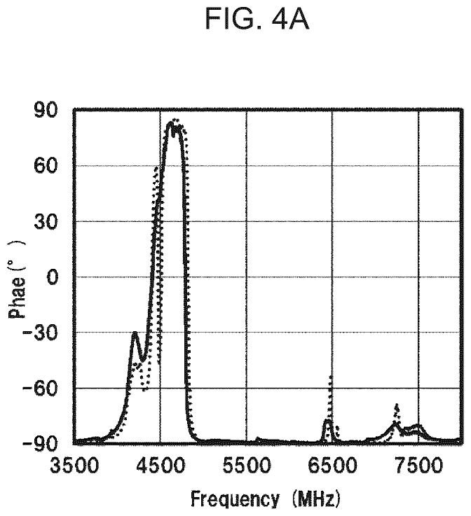

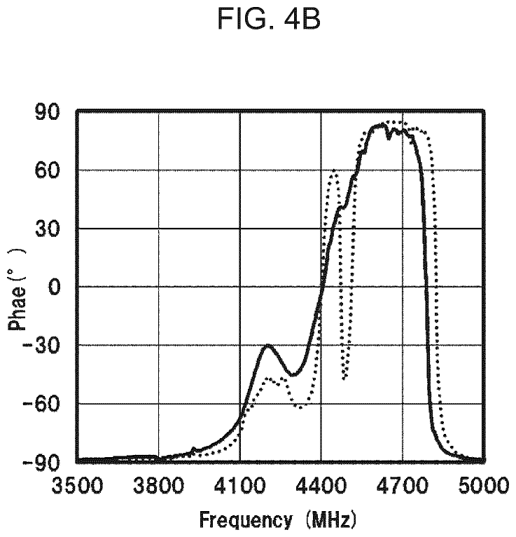

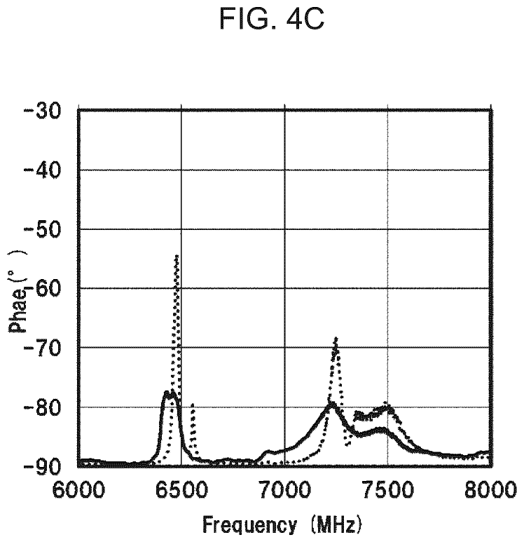

FIGS. 4A to 4C are diagrams illustrating a comparison of the resonance characteristics of the acoustic wave resonator 1 according to an Example of the present invention and the resonance characteristics of an acoustic wave resonator related to a Comparative Example. FIG. 4A illustrates the overall resonance characteristics, FIG. 4B is an enlarged view of the resonance due to the main mode, and FIG. 4C is an enlarged view of the resonance due to spurious modes. In the figures, the solid line depicts the characteristics of the Example, and the dotted line depicts the characteristics of the Comparative Example.

The design of the acoustic wave resonator 1 according to an Example of the present invention and the design of the acoustic wave resonator according to a Comparative Example are as follows.

Example (piezoelectric layer: LN, IDT electrode: A1, pitch: 2.12 μm to 2.42 μm, duty d: 0.3)

Comparative Example (piezoelectric layer: LN, IDT electrode: A1, pitch: 2.18 μm, duty d: 0.3)

In the design values of the above Example, the pitch of 2.12 μm to 2.42 μm means that the pitch increases continuously in one direction from 2.12 μm to 2.42 μm. In this case, the pitches are different from each other, so in the Example, the entire electrode finger arrangement region 7 belongs to the first region 71.

As illustrated in FIGS. 4A to 4C, the acoustic wave resonator 1 according to an Example of the present invention has reduced resonance due to spurious modes compared to the acoustic wave resonator according to a Comparative Example. On the other hand, the resonance due to the main mode has less loss than the spurious mode, and still maintains good characteristics.

The pitch of the multiple electrode fingers 412 positioned in the first region 71 is not particularly limited so long as the values are different from each other. As an example, the pitch of the multiple electrode fingers 412 positioned in the first region 71 may increase by the same amount or at the same rate in a first direction (the direction in which the electrode fingers 412 are arrayed).

For example, if there are variations in the amount or rate of increase of the pitch of the multiple electrode fingers 412 positioned in the first region 71, there will be areas where the difference in pitch is small, and the intensity of spurious at frequencies corresponding to the areas where the differences in pitch are small will be increased. On the other hand, if the pitches of multiple electrode fingers 412 increase by the same amount or at the same rate, the pitch differences will be uniform, and the waveform of resonance due to spurious modes can be effectively broadened. As a result, for example, the effect on the pass characteristics of a filter can be reduced.

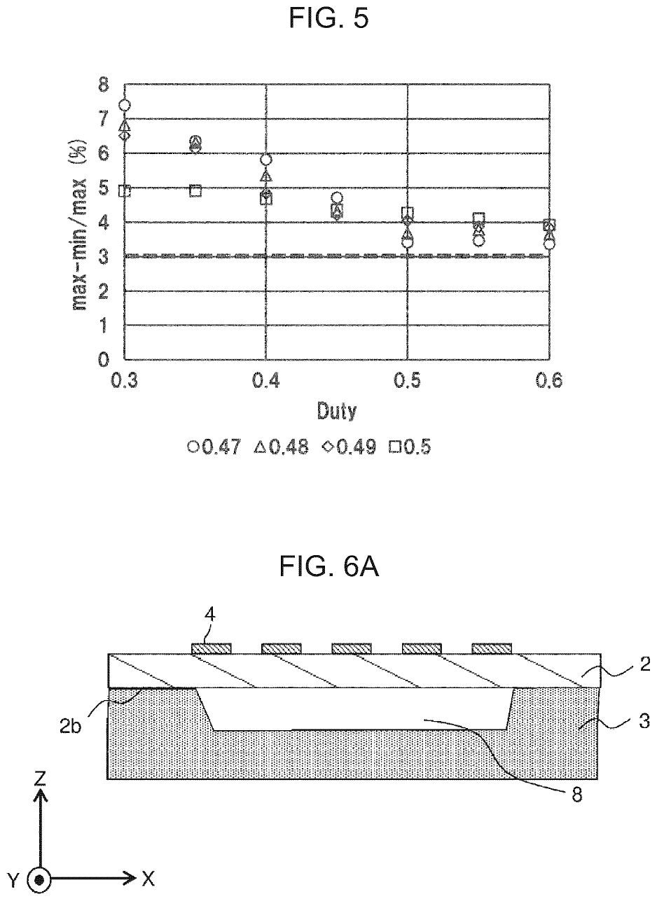

FIG. 5 is a diagram illustrating the pitch difference required to express a frequency difference of 50 MHz in a resonator with an anti-resonance frequency of 4600 MHz to 4950 MHz. The vertical axis represents the values of 100×(Pmax−Pmin)/Pmax, where Pmax is the largest pitch and Pmin is the smallest pitch out of the pitches of the multiple electrode fingers 412 positioned in the first region 71. The horizontal axis represents the values of the duty d of electrode fingers 412 positioned in the first region 71. In addition, each plot depicts changes in LN thickness in the range of 0.47 μm to 0.5 μm.

For example, the pitch of the multiple electrode fingers 412 positioned in the first region 71 may be 100×(Pmax−Pmin)/Pmax≥3.0. With this configuration, the difference between the largest pitch and the smallest pitch of the multiple electrode fingers 412 positioned in the first region 71 is greater than or equal to 50 MHz, and therefore the resonance waveform due to spurious modes can be more effectively broadened. As a result, for example, the effect on the pass characteristics of a filter can be reduced.

In the acoustic wave resonator 1 according to an embodiment of the present invention, the piezoelectric layer 2 was described as being composed of 120 ° Y-cut X propagation LN, but the piezoelectric layer 2 is not limited to this example. The Euler angles of the piezoelectric layer 2 may be set as appropriate. For example, the Euler angles of the piezoelectric layer 2 may be (0 °, θ+(α×180), 0 °) (θ is any value in the range 0 ° to 180 °, and α is an integer from 0 to 2). When the piezoelectric layer 2 has such Euler angles, the A1 mode of Lamb waves can be used effectively. In addition, for example, the piezoelectric layer 2 may be composed of Z-cut LN or LT. In this case, for example, thickness shear waves can be effectively used.

In the acoustic wave resonator 1 according to an embodiment of the present invention, the thickness of the piezoelectric layer 2 overlapping the first region 71 may be constant in plan view. With this configuration, the loss of resonance of the utilized plate waves is reduced, and the acoustic wave resonator 1 having good filter characteristics can be provided. Furthermore, “the thickness of the piezoelectric layer 2 is constant” does not necessarily mean that the thickness is strictly constant, and the thickness is allowed to vary somewhat within a range where the characteristics of acoustic waves propagating in the piezoelectric layer 2 are not significantly affected.

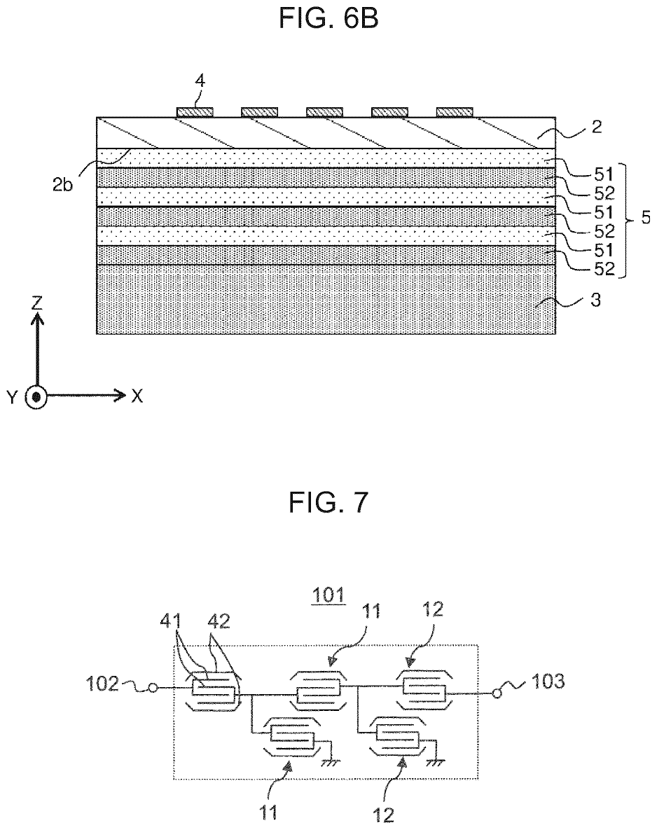

In the acoustic wave resonator 1 according to an embodiment of the present invention, the support substrate 3 is configured as illustrated in FIG. 1, but is not limited to this example. For example, as in another embodiment illustrated in FIG. 6A, the support substrate 3 may include a cavity 8 in the top surface thereof. At this time, the piezoelectric layer 2 covers the cavity 8 of the support substrate 3 in plan view, leaving a space inside the cavity 8. The size and depth of the cavity 8 may be set as appropriate.

An example is illustrated in FIG. 1 in which the piezoelectric layer 2 and the support substrate 3 are in direct contact with each other in the acoustic wave resonator 1 according to an embodiment of the present invention, but the acoustic wave resonator 1 is not limited to this example. The bottom surface 2b of the piezoelectric layer 2 and the support substrate 3 may be in direct contact with each other, or may be in indirect contact with each other with an intermediate layer, an adhesive layer, and so forth, which are not illustrated, interposed therebetween.

Examples of an insulating material that can be used as such an intermediate layer include silicon oxide (SiO₂), silicon nitride (Si₃N₄), and aluminum oxide (Al₂O₃). By providing such an insulating layer, the formation of unwanted potentials and unwanted capacitances can be reduced, and the electrical characteristics of the acoustic wave resonator 1 can be improved.

In addition, both an adhesive layer and an intermediate layer may be positioned between the piezoelectric layer 2 and the support substrate 3. For example, if both the adhesive layer and the intermediate layer are positioned between the piezoelectric layer 2 and the support substrate 3, the adhesive layer is positioned between the support substrate 3 and the intermediate layer. Examples of such an adhesive layer include amorphous silicon.

As another example, an alumina film, etc., which is not illustrated, may be additionally positioned between the intermediate layer and the piezoelectric layer 2. When such an alumina film is present, the leakage of acoustic waves from the piezoelectric layer 2 to the support substrate 3 can be reduced, and the frequency characteristics of the acoustic wave resonator 1 can be improved.

FIG. 6B is a schematic sectional view of the acoustic wave resonator 1 according to yet another embodiment. In the embodiment illustrated in FIG. 6B, a multilayer film layer 5 may be positioned between the piezoelectric layer 2 and the support substrate 3. The multilayer film layer 5 consists of low-acoustic-impedance layers 51 and high-acoustic-impedance layers 52 stacked in an alternating manner. The acoustic impedance of the low-acoustic-impedance layers 51 is lower than that of the piezoelectric layer 2, and the acoustic impedance of the high-acoustic-impedance layers 52 is higher than that of the low-acoustic-impedance layers 51. For example, the low-acoustic-impedance layers 51 are composed of silicon oxide (SiO₂), and the high-acoustic-impedance layers 52 are composed of hafnium oxide (HfO₂).

In an embodiment of the present invention, in the acoustic wave resonator 1, the duty d of the electrode fingers 412 positioned in the first region 71 may be constant. Since the pitches of the electrode fingers 412 in the first region 71 are different from each other, if the value of the duty d of the electrode fingers 412 in the first region 71 is constant, the possibility of spurious occurring due to unexpected resonance can be reduced compared to when the duty d varies, and spurious can be effectively reduced. For example, the value of the duty d of the electrode fingers 412 positioned in the first region 71 is less than or equal to 0.6. “The value of the duty d is constant” does not necessarily mean that the duty d is strictly constant, and for example, some variation within a range of 0.01 or less is allowed.

In the acoustic wave resonator 1 according to an embodiment of the present invention, the thickness of the electrode fingers 412 positioned in the first region 71 may be constant, or may be set as appropriate to a different thickness for each electrode finger 412.

In the acoustic wave resonator 1 according to an embodiment of the present invention, an assumption is made that the first region 71 may occupy an area of at least half the electrode finger arrangement region 7, but the configuration is not limited to this example. For example, the number of electrode fingers 412 positioned in the first region 71 may be greater than or equal to half the total number of multiple electrode fingers 412 positioned in the electrode finger arrangement region 7. With this configuration, the region in which the pitches of the electrode fingers 412 are different from each other is dominant, and the generation of spurious can be more effectively reduced.

The specific number of electrode fingers 412 positioned in the first region 71 is not particularly limited. In theory, the number is three or more, with there being two or more pitches, and in practice, for example, the number may be five or more, ten or more, thirty or more, fifty or more, or one hundred or more.

In the acoustic wave resonator 1 according to an embodiment of the present invention, an assumption is made that the pitches of all the electrode fingers 412 in the first region 71 may be different from each other, but the configuration is not limited to this example. For example, in a central region when the electrode finger arrangement region 7 is divided into three equal parts, the pitches of the electrode fingers 412 may increase as one moves towards one side in the first direction (the direction in which the electrode fingers 412 are arrayed). When saying this, the central region may include parts with a constant pitch. From another perspective, the pitch may increase in a step-like manner (in steps) rather than continuously increasing in part or the entirety of the central region. Even in this case, the effects such as broadening are obtained.

The number of pitch changes in the central region is not particularly limited. The number of changes is theoretically greater than or equal to 1, and in practice, for example, may be five or more, ten or more, thirty or more, fifty or more, or one hundred or more.

### Usage Example of Acoustic Wave Resonator 1: Acoustic Wave Filter

FIG. 7 is a circuit diagram schematically illustrating the configuration of an acoustic wave filter 101 as a usage example of the acoustic wave resonator 1. In this figure, the comb-shaped electrodes 41 are each schematically illustrated in the shape of a two-pronged fork, and the reflectors 42 are each represented by a single line bent at both ends, as indicated by the symbols in the upper left corner of the figure.

The acoustic wave filter 101, for example, filters a signal input from an input terminal 102 and outputs the resulting signal to an output terminal 103.

The acoustic wave filter 101 is configured, for example, as a ladder filter consisting of multiple resonators connected in a ladder configuration. In other words, the acoustic wave filter 101 includes multiple (or just one) resonators (series resonators) connected in series between the input terminal 102 and the output terminal 103, and multiple (or just one) resonators (parallel resonators) connected between the series line and a reference potential.

In this embodiment, at least one of the resonators of the acoustic wave filter 101 is the acoustic wave resonator 1 of this embodiment. For convenience, the resonators constituted by the acoustic wave resonator 1 are referred to as first acoustic wave resonators 11.

The acoustic wave filter 101 further includes second acoustic wave resonators 12. For example, if the first acoustic wave resonators 11 and the second acoustic wave resonators 12 are series resonators, the anti-resonance frequency of the second acoustic wave resonators 12 may be positioned closer to the passband of the acoustic wave filter 101 than the anti-resonance frequency of the first acoustic wave resonators 11 is.

In the IDT electrode 4 of the first acoustic wave resonators 11, the largest pitch and the smallest pitch, among the pitches of the electrode fingers 412 positioned in the first region 71, are defined as P1max and P1min, respectively, and the largest pitch and the smallest pitch, among the pitches of the multiple electrode fingers of the IDT electrode 4 of the second acoustic wave resonators 12, are defined as P2max and P2min, respectively. In this case, the acoustic wave filter 101 may be designed so that (P2max−P2min) is smaller than (P1max−P1min).

With this configuration, the second acoustic wave resonators 12 have a smaller pitch difference than the first acoustic wave resonators 11. In general, resonators having a small pitch difference have a smaller loss of resonance in the main mode than resonators having a large pitch difference. Therefore, the anti-resonance frequency of the second acoustic wave resonators 12, which have a smaller pitch difference than the first acoustic wave resonators 11, is positioned between the anti-resonance frequency of the first acoustic wave resonators 11 and the passband of the acoustic wave filter 101, and as a result, the loss of the main mode of the resonators located near the passband of the filter can be reduced. Therefore, an acoustic wave filter with steep filter characteristics can be provided.

In addition, if the first acoustic wave resonators 11 and the second acoustic wave resonators 12 are parallel resonators, the resonance frequency of the second acoustic wave resonators 12 may be positioned closer to the passband of the acoustic wave filter 101 than the resonance frequency of the first acoustic wave resonators 11 is. In this case, the acoustic wave filter 101 may be designed so that (P2max−P2min) is smaller than (P1max−P1min).

With this configuration, the second acoustic wave resonators 12 have a smaller pitch difference than the first acoustic wave resonators 11. Therefore, the anti-resonance frequency of the second acoustic wave resonators 12, which have a smaller pitch difference than the first acoustic wave resonators 11, is positioned between the anti-resonance frequency of the first acoustic wave resonators 11 and the passband of the acoustic wave filter 101, and as a result, the loss of the main mode of the resonators located near the passband of the filter can be reduced. Therefore, an acoustic wave filter with steep filter characteristics can be provided.

When the acoustic wave filter 101 is a band elimination filter, the maximum phase of spurious originating from the first acoustic wave resonators 11 and present in the passband of the acoustic wave filter 101 may be less than or equal to −70 °. For example, the maximum phase of the spurious originating from the first acoustic wave resonator 11 and present in the passband of the acoustic wave filter 101 may be positioned in the range of −80 °to −70 °.

With this configuration, spurious having a small phase is positioned in the passband of the acoustic wave filter 101, and the effect of spurious on the filter can be reduced.

The acoustic wave filter 101 is illustrated as a ladder filter as an example, but is not limited to this example. For example, the acoustic wave filter 101 may be a multi-mode filter (including a double-mode filter). The multi-mode filter includes multiple IDT electrodes 4 arrayed in the propagation direction of acoustic waves and a pair of reflectors 42 disposed on both sides of the IDT electrodes.

### Usage Example of Acoustic Wave Resonator 1: Communication Device

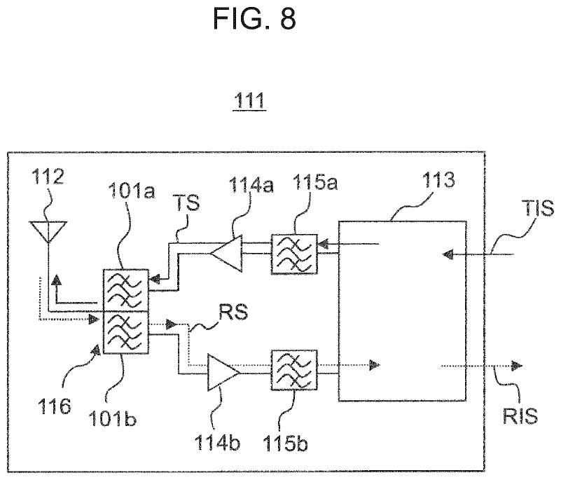

FIG. 8 is a block diagram illustrating the main components of a communication device 111 as a usage example of the acoustic wave resonator 1 and the acoustic wave filter 101. The communication device 111 performs wireless communication using radio waves and includes a splitter 116. The splitter 116 includes a transmission filter 101a and a reception filter 101b. At least one of the transmission filter 101a or the reception filter 101b is configured by the acoustic wave filter 101. The output side of the transmission filter 101a and the input side of the reception filter 101b are both connected to an antenna 112.

In the communication device 111, a transmission information signal TIS, which contains information to be transmitted, is modulated and raised in frequency (converted to a radio-frequency signal having a carrier frequency) by a RF-IC (radio frequency integrated circuit) 113, and becomes a transmission signal TS. Unwanted components outside a transmission passband are removed from the transmission signal TS by a bandpass filter 115a, and the resulting transmission signal TS is then amplified by an amplifier 114a and input to the splitter 116 (transmission filter 101a). The splitter 116 (transmission filter 101a) removes unwanted components outside the transmission passband from the input transmission signal TS, and then outputs the resulting transmission signal TS to the antenna 112. The antenna 112 converts the input electrical signal (transmission signal TS) into a radio signal (radio waves) and transmits the radio signal.

In the communication device 111, a radio signal (radio waves) received by the antenna 112 is converted into an electrical signal (reception signal RS) by the antenna 112 and input to the splitter 116. The splitter 116 (reception filter 101b) removes unwanted components outside a reception passband from the input reception signal RS and outputs the resulting reception signal RS to an amplifier 114b. The output reception signal RS is amplified by the amplifier 114b, and unwanted components outside the reception passband are removed by a bandpass filter 115b. The reception signal RS is then reduced in frequency and demodulated by the RF-IC 113, and becomes a reception information signal RIS.

The transmission information signal TIS and the reception information signal RIS may be low-frequency signals (baseband signals) containing appropriate information, for example, analog or digitized audio signals. The radio signal passband may be set as appropriate, and in this embodiment, a relatively high frequency passband (for example, 5 GHz or higher) is also possible. The modulation method may be phase modulation, amplitude modulation, frequency modulation, or a combination of any two or more of these methods. Although the direct conversion method is illustrated as an example in FIG. 8, other types of circuit may be used as appropriate, for example, a double superheterodyne type circuit. FIG. 8 is a diagram schematically illustrating only the main components, and a low-pass filter, an isolator, and so on may be added at appropriate positions, and the positions of amplifiers and so on may be changed.

### REFERENCE SIGNS

1 acoustic wave resonator
2 piezoelectric layer
2a top surface
2b bottom surface
3 support substrate
4 IDT electrode
41 comb-shaped electrode
411 busbar
412 electrode finger
42 reflector
5 multilayer film layer
7 electrode finger arrangement region
71 first region
72 second region
8 cavity
11 first acoustic wave resonator
12 second acoustic wave resonator
101 acoustic wave filter
102 input terminal
103 output terminal
111 communication device
112 antenna
113 RF-IC
114a, 114b amplifier
115a, 115b bandpass filter

1. An acoustic wave resonator comprising:
a piezoelectric layer having a piezoelectric property; and
an IDT electrode positioned on a first surface of the piezoelectric layer and including multiple electrode fingers arrayed in a first direction,
wherein an entirety of each of the multiple electrode fingers is positioned in an electrode finger arrangement region,
when a distance from one side of one electrode finger to a corresponding one side of the electrode finger adjacent to the one electrode finger in the first direction is defined as a pitch of the one electrode finger,
the electrode finger arrangement region includes a first region in which the pitches of all the electrode fingers are different from each other, and
the acoustic wave resonator is configured so that a plate wave or a bulk wave is used as an acoustic wave that propagates through the electrode finger arrangement region.

2. The acoustic wave resonator according to claim 1, wherein the first region occupies at least half an area of the electrode finger arrangement region.

3. The acoustic wave resonator according to claim 1, wherein an area near a center of the electrode finger arrangement region in the first direction belongs to the first region.

4. The acoustic wave resonator according to claim 1, wherein an entirety of the electrode finger arrangement region belongs to the first region.

5. The acoustic wave resonator according to claim 1, wherein the pitches of the multiple electrode fingers positioned in the first region increase by a same amount or at a same rate in the first direction.

6. The acoustic wave resonator according to claim 1,
wherein when Pmax is a largest pitch and Pmin is a smallest pitch, among the pitches of the multiple electrode fingers positioned in the first region,
100×(Pmax−Pmin)/Pmax≥3.0.

7. The acoustic wave resonator according to claim 1, wherein the acoustic wave is a plate wave and is a Lamb wave A1 mode.

8. The acoustic wave resonator according to claim 1, wherein the acoustic wave is a bulk wave and is a thickness shear wave.

9. The acoustic wave resonator according to claim 1,
wherein when a width of one electrode finger in the first direction is defined as a width of the one electrode finger, and
width/pitch is defined as a duty d of the one electrode finger,
the duty d of the multiple electrode fingers positioned in the first region is constant.

10. The acoustic wave resonator according to claim 9, wherein the duty d is less than or equal to 0.6 in the multiple electrode fingers positioned in the first region.

11. The acoustic wave resonator according to claim 1, wherein a thickness of the multiple electrode fingers positioned in the first region is constant.

12. The acoustic wave resonator according to claim 1, wherein a thickness of the piezoelectric layer overlapping the first region in plan view is constant.

13. The acoustic wave resonator according to claim 12,
wherein when λ is defined as twice a largest pitch among the pitches of the multiple electrode fingers positioned in the first region,
a thickness of the piezoelectric layer is less than or equal to 2λ.

14. An acoustic wave resonator comprising:
a piezoelectric layer having a piezoelectric property; and
an IDT electrode positioned on a first surface of the piezoelectric layer and including multiple electrode fingers arrayed in a first direction,
wherein an entirety of each of the multiple electrode fingers is positioned in an electrode finger arrangement region, and
when a distance from one side of one electrode finger to a corresponding one side of the electrode finger adjacent to the one electrode finger in the first direction is defined as a pitch of the one electrode finger,
the pitches of the electrode fingers increase in a direction toward the one side in a central region obtained when the electrode finger arrangement region is divided into three equal parts in the first direction.

15. An acoustic wave filter that is a ladder acoustic wave filter, the acoustic wave filter comprising:
multiple series arm resonators connected in series with each other and including the acoustic wave resonator according to claim 1 and a second acoustic wave resonator; and
a parallel arm resonator connected in parallel with the series arm resonators,
wherein an anti-resonance frequency of the second acoustic wave resonator is positioned closer to a passband of the acoustic wave filter than an anti-resonance frequency of the acoustic wave resonator is, and
when P1max is defined as a largest pitch and P1min is defined as a smallest pitch among the pitches of the multiple electrode fingers of the IDT electrode of the acoustic wave resonator and
P2max is defined as a largest pitch and P2min is defined as a smallest pitch among pitches of multiple electrode fingers of an IDT electrode of the second acoustic wave resonator,
(P2max−P2min) is smaller than (P1max−P1min).

16. An acoustic wave filter that is a ladder filter, the acoustic wave filter comprising:
a series arm resonator connected in series; and
multiple parallel arm resonators connected in parallel with the series arm resonator and including the acoustic wave resonator according to claim 1 and a second acoustic wave resonator,
wherein a resonance frequency of the second acoustic wave resonator is positioned closer to a passband of the acoustic wave filter than a resonance frequency of the acoustic wave resonator is, and
when P1max is defined as a largest pitch and P1min is defined as a smallest pitch among the pitches of the multiple electrode fingers of the IDT electrode of the acoustic wave resonator and
P2max is defined as a largest pitch and P2min is defined as a smallest pitch among pitches of multiple electrode fingers of an IDT electrode of the second acoustic wave resonator,
(P2max−P2 min) is smaller than (P1max−P1min).

17. An acoustic wave filter comprising:
the acoustic wave resonator according to claim 1,
wherein a maximum phase of spurious originating from the acoustic wave resonator and present in a passband of the acoustic wave filter is less than or equal to −70 °.

18. A communication device comprising: an antenna;
an acoustic wave filter connected to the antenna; and
an IC connected to the acoustic wave filter,
wherein the acoustic wave filter includes the acoustic wave resonator according to claim 1.
